(19) United States
(12) Patent Application Publication
(10) Pub. No.: US 2008/0224155 A1
(43) Pub. Date: Sep. 18, 2008

(54) LIGHT-EMITTING DIODE UNIT

(75) Inventors: Koichi Fukasawa, Kofu-shi (JP); Mitsunori Ishizaka, Minamitsuru-gun (JP)

Correspondence Address: BROWDY AND NEIMARK, P.L.L.C.;624 NINTH STREET, NW, SUITE 300, WASHINGTON, DC, 20001-5303, US

(73) Assignee: CITIZEN ELECTRONICS CO., LTD., Fujiyoshida-shi (JP)

(21) Appl. No.: 12/048,639

(22) Filed: Mar. 14, 2008

(30) Foreign Application Priority Data
Mar. 15, 2007 (JP) 2007-066091

(51) Int. Cl. H01L 33/00

(52) U.S. Cl. 257/89; 257/E33.001

(57) ABSTRACT

An LED unit including a frame (17) and a plurality of LED elements (11, 12, 13) which emit three primary colors of light and are sealed in the frame (17), readable characteristic data such as drive conditions, characteristics of each of the plurality of LED elements (11, 12, 13) being displayed on a surface of the frame.

### CROSS-REFERENCE TO THE RELATED APPLICATION

This application is based on and claims the priority benefit of Japanese Patent Application No. 2007-066091, filed on Mar. 15, 2007, the disclosure of which is incorporated herein by reference in its entirety.

### BACKGROUND OF THE INVENTION

1. Field of the Invention

The present invention relates to a light-emitting diode (LED) unit, more specifically to an LED unit in which characteristic data of each of LED elements are displayed on a surface of a package configured to include the LED elements.

2. Description of Related Art

The practice of displaying a lot number or the like on each of electronic parts is generally known. When a lot trace for a conventional small electronic part is required, the problem arises that an individual lot of the electronic part cannot be discriminated because displayed information is insufficient. Therefore, a technology has been proposed in which lot numbers comprising date of manufacture and serial number of the small electronic part are displayed on a surface of the electronic part to improve lot traceability (for reference, see JP 6-325967A, page 2 in the specification and FIG. 1).

FIG. 4 illustrates a display part provided on a surface of a conventional small electronic part, and FIG. 5 is a schematic view to explain codes used for the display part shown in FIG. 4. The small electronic part includes a name 3 of product provided on a surface of an exterior resin 2 having an electrode 1 and a lot number code 4a which is also used as a polar display and provided by a laser marker.

When the lot number code is displayed by date of manufacture and serial number in the month, then, if the electronic part is, for example, the eight to be produced in March, 1993, the year of manufacture is 3, the month of manufacture is 03, and the serial number is 008, so that the lot number code 4a is shown by the six digit number “303008”. Here, as shown in FIG. 5, number 1 is displayed at the right lower side of the code display part, number 2 at the right upper side of the code display part, number 3 at the lower side of the next row, number 4 at the upper side of the next row, number 7 at the left lower side of the code display part, and number 8 at the left upper side of the code display part.

The lot number is formed by attaching codes “5 to 7” to positions corresponding to these numbers, respectively. That is to say, in the lot number codes, the production year is shown by right slash 5 (see FIG. 6A), the production month by left slash 6 (see FIG. 6B), and serial number by a filled portion 7 (see FIG. 6C). Here, if the codes are overlapped, the lot number codes are shown as an overlapped portion 9 (see FIG. 6D).

On the other hand, a plurality of LED elements have recently come to be used in LED unit which is one type of small electronic part on account of the increasing brightness and diversity emission color of light. It is required that characteristics such as emission intensity or the like are generally uniform in the LED elements used for such LED units. Therefore, the LED elements are previously selected and lot numbers are provided on a surface of the LED unit to achieve traceability of the LED unit. However, when an LED element in which brightness and color fall within a predetermined standard is selected from a large number of produced LED elements, if a broader standard is adopted, variations in light emitted from each of LED elements are generated, and therefore, products of the LED unit have uneven characteristics for emission.

Also, if a narrower standard is adopted, there is a narrowing in the range of use of the produced LED elements and consequent lowered usage rate. Therefore, the characteristics of individual LED elements constituting the LED unit are previously measured, a data sheet on which the characteristics are described is presented, and the individual LED elements are controlled on the basis of the data sheet.

However, in the aforementioned conventional art, because the LED unit and the data sheet come separately, when the individual LED elements are controlled on the basis of the data sheet, selection error for the data sheet may occur, and hence the case may arise that the LED unit and the data sheet do not correspond. Consequently, there is a problem that variations in emission color of light among the produced LED units occur and predetermined brightness and emission color are not achieved.

### SUMMARY OF THE INVENTION

An object of the present invention is to provide an LED unit in which a display part showing characteristic data of each of a plurality of LED elements is provided on a surface of a package including the plurality of LED elements, in which the display part showing the characteristic data can be read, and in which drive conditions based on the read characteristic data can be input into an LED driver circuit, thereby preventing input errors and variations in brightness and emission color of light.

To accomplish the above object, an LED unit according to one embodiment of the present invention includes a package, and a plurality of LED elements disposed in the package.

Readable characteristic data of each of the plurality of LED elements are displayed on a surface of the package. The characteristic data of each of the LED elements include drive voltage, drive current, emission intensity, emission wavelength, forward voltage, temperature characteristics or the like.

The characteristic data of each of the LED elements are values which are obtained by applying electricity to each of the LED elements and measuring the characteristics thereof. In one embodiment, the characteristic data are formed by a laser marker.

### BRIEF DESCRIPTION OF THE DRAWINGS

FIG. 1A is a plan view of an LED unit according to an embodiment of the present invention.

FIG. 1B is a sectional view taken along line A-A in FIG. 1A.

FIG. 2 is a schematic view explaining codes corresponding to characteristic data displayed on a surface of the LED unit according to the embodiment of the present invention.

FIG. 3 is a view showing a relationship between characteristic data and codes showing the characteristic data of LED elements in the embodiment of the present invention.

FIG. 4 is a view showing a display of lot numbers or the like on a surface of a small electronic part in conventional art.

FIG. 5 is a schematic view explaining codes of the lot numbers used in FIG. 4.

FIG. 6A is an explanatory view showing a concrete example of the lot number codes as shown in FIG. 5.

FIG. 6B is an explanatory view showing another concrete example of the lot number codes as shown in FIG. 5.

FIG. 6C is an explanatory view showing yet another concrete example of the lot number codes as shown in FIG. 5.

FIG. 6D is an explanatory view showing yet another concrete example of the lot number codes as shown in FIG. 5.

### DETAILED DESCRIPTION OF THE PREFERRED EMBODIMENTS

Preferred embodiments of the present invention will be explained in detail below with reference to the accompanying drawings.

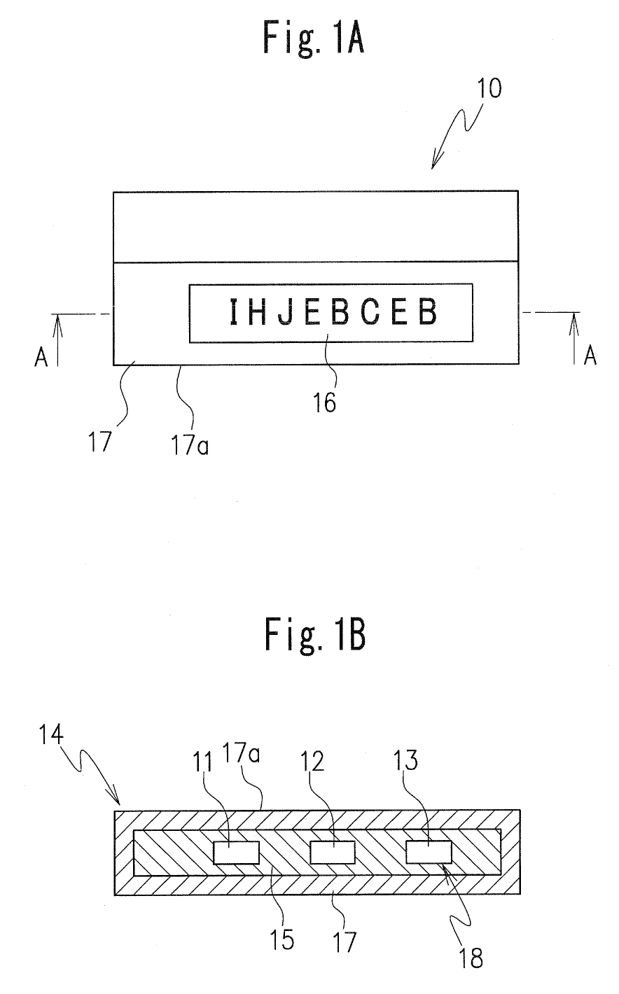

FIG. 1A illustrates a light emitting diode (LED) unit 10 according to one embodiment of the present invention. The LED unit 10 in this embodiment includes a package 14 and a plurality of LED elements 18 disposed in the package 14 (see FIG. 1B). The package 14 includes a frame 17 which is made, for example, from a white resinous material and, for example, a heat-hardening resin 15 which is disposed in the frame 17 and configured to seal the plurality of LED elements 18 (see FIG. 1B). The resin 15 to seal LED elements mounted on a substrate is a light-transmitting resin.

The LED elements 18 comprise, for example, a red (R) LED element 11, a green (G) LED element 12 and a blue (B) LED element 13, which emit the three primary colors of light. Any color of light can be acquired by mixing the three primary colors of light emitted from the RGB LED elements 11, 12, and 13. Moreover, white light can be acquired by mixing the three primary colors of light emitted from the RGB LED elements 11, 12, and 13. Furthermore, white light can be acquired by mixing two complementary colors of light emitted from LED elements.

In this way, although white light can be acquired by mixing the light emitted from the red LED element 11, the green LED element 12 and the blue LED element 13, it is necessary to accurately control light emitted from each of the red LED element 11, the green LED element 12 and the blue LED element 13, to obtain white light better suited to the conditions of use or the like or to prevent the package or the like from becoming excessively white due to the influence of the white light emitted from the three LED elements.

This necessity can be accomplished by reading characteristic data of the LED elements, which are provided on the package, as mentioned below.

It should be noted that, in the embodiment, LED elements 18 emitting different colors are used, but LED elements emitting the same color may be used.

A display part 16 to display characteristic data of each of the LED elements 18 is provided on a surface of the package 14, for example, a surface 17a of the frame 17. In other words, in this embodiment, the display part 16 is provided on the surface 17a of the frame to display the characteristic data of each of the red LED element 11, the green LED element 12 and the blue LED element 13. In one embodiment, the display part 16 is formed by providing codes showing the characteristic data of each of the red LED element 11, the green LED element 12 and the blue LED element 13. The display part 16 is formed to be read by a reader (not shown).

Here, the characteristic data of each of the LED elements include drive conditions or characteristics, for example, a drive voltage, drive current, emission intensity, emission wavelength, forward voltage, temperature characteristics or the like. Even if LED elements are made from the same wafer, there will be variations in characteristics even at normal temperature (25° C.).

In the case of LED elements of different types, the difference among the LED elements will of course be all the greater. In addition, an LED element has characteristics which change according to changes in temperature other than the variation in characteristics at normal temperature.

Therefore, it is required that characteristic data such as drive voltage or the like of the LED element at normal temperature or a temperature are previously displayed on the package 14, the displayed data are read and the LED element can be suitably controlled according to the read data. Thereby, it is possible to accurately control lighting of the LED element.

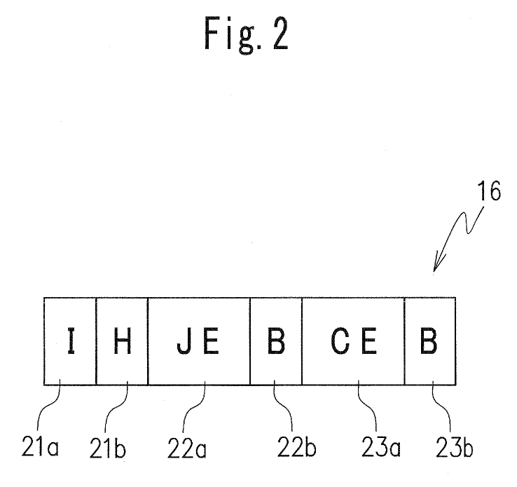

As shown in FIG. 2, areas showing the characteristic data of emission intensity and emission wavelength (peak value) of each of the LED elements are provided on the display part 16. The areas include a display area 21a for emission intensity of the red LED element 11, a display area 21b for emission wavelength of the red LED element 11, a display area 22a for emission intensity of the green LED element 12, a display area 22b for emission wavelength of the green LED element 12, a display area 23a for emission intensity of the blue LED element 13, and a display area 23b for emission wavelength of the blue LED element 13, which are arranged in order from the left side of the display part 16. In addition, codes I, H, JE, B, CE and B are provided on the areas corresponding to the characteristic data.

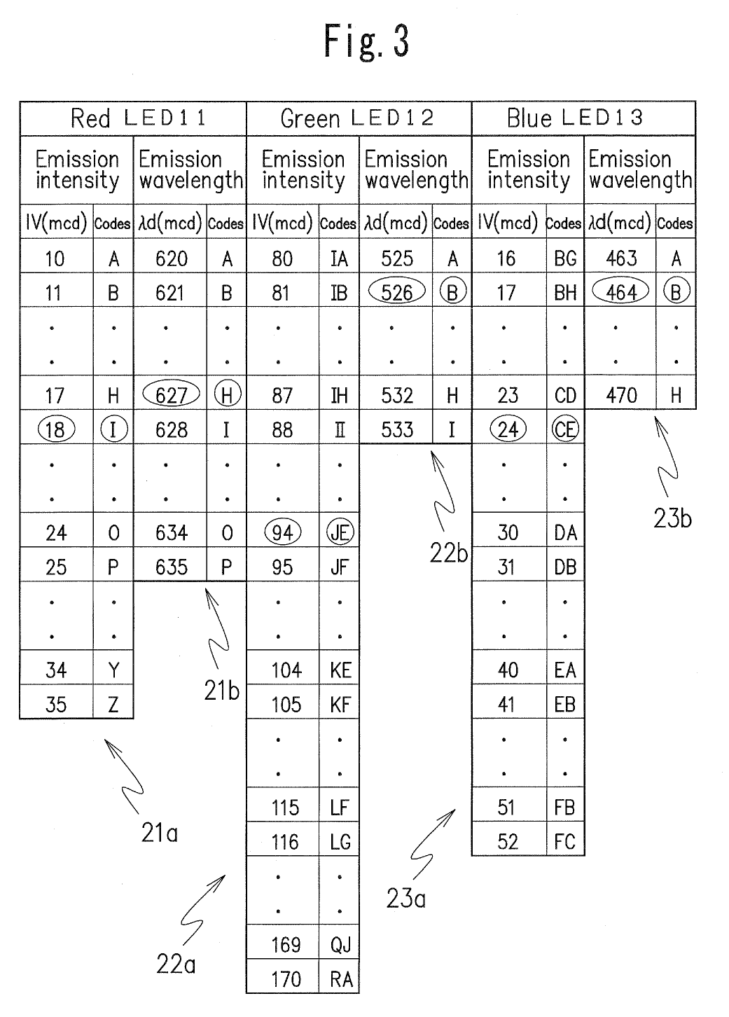

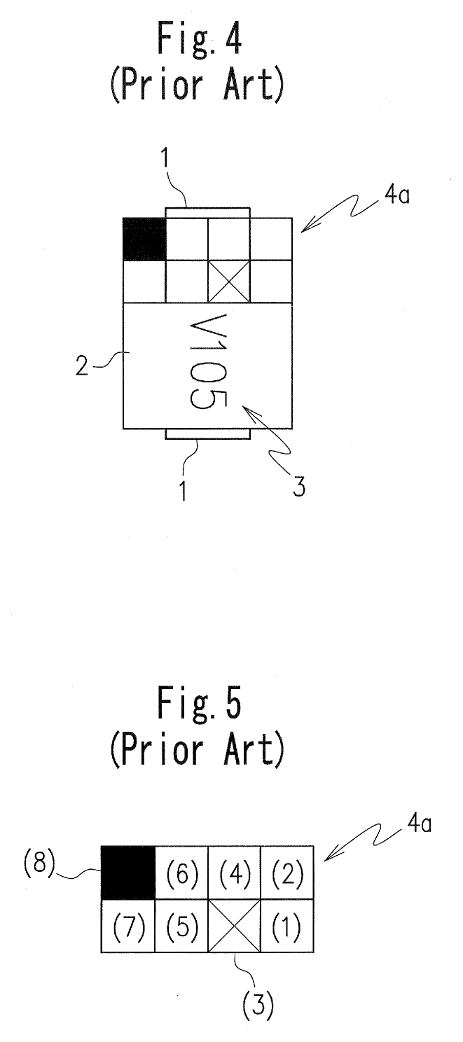

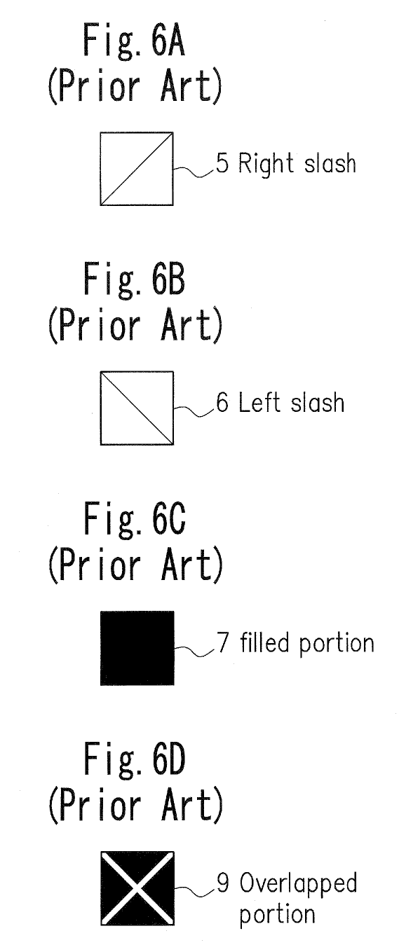

Next, a concrete example of the codes showing the characteristic data of each LED element is described with reference to FIGS. 2 and 3.

As shown in FIG. 2, the code I is provided on the display area 21a for emission intensity of the red LED element 11. The code I displays that the emission intensity Iv of the red LED element 11 is 18 (mcd), as shown in FIG. 3. The code H is provided on the next display area 21b, as shown in FIG. 2. The code H displays that the emission wavelength λd of the red LED element 11 is 627 (nm), as shown in FIG. 3.

Similarly, the code JE on the display area 22a displays that the emission intensity Iv of the green LED element 12 is 94 (mcd), the code B on the display area 22b displays that the emission wavelength λd of the green LED element 12 is 526 (nm), the code CE on the display area 23a displays that the emission intensity Iv of the blue LED element 13 is 24 (mcd), and the code B on the display area 23b displays that the emission wavelength λ_{d} of the blue LED element 13 is 464 (nm).

The characteristic data of each LED element provided as mentioned above are values which are obtained by applying electricity to each of the red LED element 11, the green LED element 12 and the blue LED element 13, which are mounted on the LED unit 10, and measuring the characteristics thereof.

The code showing the characteristic data of each LED element is marked by a laser marker, and hence because the code marked by the laser marker in this way is formed by a groove provided by means of a laser, there is no danger that the provided code is difficult to see even after execution of a reflow for the LED unit, or that it is cleared even if a surface of the code is rubbed.

The codes showing the characteristic data may be provided by printing or the like. If the LED unit according to the present invention has a relatively small size, the codes are preferably marked by laser, whereas if it has a relatively large size, they may be by printing.

Meanwhile, the red LED element 11, the green LED element 12 and the blue LED element 13 are connected to an LED driver circuit (not shown) which drives the LED elements. The LED driver circuit is mounted on, for example, a mother board (not shown) together with the LED unit.

When the display part 16 is read by the aforementioned reader (not shown), the characteristic data of each of the red LED element 11, the green LED element 12 and the blue LED element 13 are read, a user can input the drive conditions into the LED driver circuit in accordance with the read characteristic data, and it is thereby possible to provide an LED unit without input errors and variations in brightness or emission color.

The display part 16 is provided at a position where it is visible, for example, an upper surface or side surface of the frame 17, when the package 14 is mounted on an upper surface or side surface of the mother board.

Next, a concrete method to control brightness or emission color of the LED unit on which the characteristic data are displayed is described.

The red LED element 11, the green LED element 12 and the blue LED element 13 are controlled in accordance with the measured values of emission intensity and emission wavelength of each of the red LED element 11, the green LED element 12 and the blue LED element 13, which are obtained from the characteristic data provided on the surface of the package 14, so that if the brightness is higher than a target value, an input current is reduced, and if the brightness is lower than the target value, the input current is increased.

Also, in the case of emission wavelength, the emission wavelength is shifted by increasing a current value to be input, but because the emission intensity also simultaneously increases, an actual state is adjusted or returned to an original state, with a pulse drive (PWM drive). For example, if the current value doubles, a duty ratio may be set to be about 2 to 3.

If the LED unit 10 in the embodiment is mounted on a mobile phone or the like, the variations in brightness or emission color can be controlled by reading the codes provided on the surface of the package 14 by a camera or the like (not shown) and inputting the drive conditions of each LED element into the LED driver circuit.

It should be noted that the LED driver circuit is mounted on the mobile phone or the like together with the LED unit 10.

In this way, because the LED unit in the embodiment can read directly the codes displaying the characteristic data of each of the LED elements, which are provided on the surface of the package, it is possible to prevent any misreading of the characteristic data of the LED elements.

In addition, in the LED unit in the embodiment, it is possible to mount an LED element having various emission intensities and emission wavelengths which are not ranked. Therefore, it is possible to provide an inexpensive LED unit without requiring selection operation of the LED element.

Furthermore, in the aforementioned embodiment, as an example, English characters have been used as the codes showing the characteristic data of the LED elements, however, the embodiment is not limited to this manner. Various data codes such as numbers, bar code, data matrix or the like may be appropriately used.

It should be noted that use of a data matrix is preferable since a great deal of information can be displayed on small areas.

Any code may be used, but the codes allowing greatest amount of input data for a given area are, in descending order, two-dimensional code, bar code, character and number. A matrix system of two-dimensional code can be read in all directions.

There is a possibility that dust becomes attached even if the two-dimensional code is displayed by a laser or that flux becomes attached in a reflow process of the LED unit. However, if the broken area of the two-dimensional code is of the order of 20 to 30%, the code can be read.

Consequently, if laser marking and the two-dimensional code are used together, it is difficult for recognition (reading) errors of the display part 16 to occur by thin spot, contamination or the like.

As mentioned above, the LED unit according to the present invention makes it possible to form the display part showing the characteristic data of each of the LED elements on the surface of the package sealing the LED elements, read directly the characteristic data of the display part, and input the drive conditions or the like of the LED elements in the LED driver circuit which is mounted on the mother board or the like together with the LED unit, based on the characteristic data. Accordingly, it is possible to provide an LED unit without input errors and variations in brightness or emission color.

Although the preferred embodiments of the present invention have been described, it should be noted that the present invention is not limited to these embodiments, and various modifications and changes can be made to the embodiments.

What is claimed is:

1. A light-emitting diode unit, comprising:
a package; and
a plurality of light-emitting diode elements disposed in the package;
readable characteristic data of each of the plurality of light-emitting diode elements being displayed on a surface of the package.

2. The light-emitting diode unit according to claim 1,
wherein the package includes a frame and a sealing member disposed in the frame, and the sealing member is configured to seal the plurality of light-emitting diode elements.

3. The light-emitting diode unit according to claim 1,
wherein the plurality of light-emitting diode elements are configured to emit different emission colors of light with respect to each other.

4. The light-emitting diode unit according to claim 1,
wherein the characteristic data include drive conditions and characteristics of each of the light-emitting diode elements.

5. The light-emitting diode unit according to claim 1,
wherein the characteristic data of each of the light-emitting diode elements include drive voltage, drive current, emission intensity, emission wavelength, forward voltage or temperature characteristics.

6. The light-emitting diode unit according to claim 4,
wherein the characteristics of each light-emitting diode element are values measured when electricity is applied to each of the plurality of light-emitting diode elements.

7. The light-emitting diode unit according to claim 1,
wherein the characteristic data is provided by a laser marker.

8. The light-emitting diode unit according to claim 1,
wherein the characteristic data is read by a reader, and
wherein, on reading of the characteristic data, each of the light-emitting diode elements is controlled by a light-emitting diode driver circuit on the basis of the read characteristic data.
